(19) United States
(12) Patent Application Publication
(10) Pub. No.: US 2016/0064536 A1
(43) Pub. Date: Mar. 3, 2016

(54) SEMICONDUCTOR DEVICE

(71) Applicant: Kabushiki Kaisha Toshiba, Tokyo (JP)

(72) Inventors: Bungo Tanaka, Ageo Saitama (JP); Tomoko Matsudai, Shibuya Tokyo (JP); Yuuichi Oshino, Fuchu Tokyo (JP)

(21) Appl. No.: 14/637,192

(22) Filed: Mar. 3, 2015

(30) Foreign Application Priority Data
Aug. 28, 2014 (JP) 2014-173984

(51) Int. Cl. H01L 29/739; H01L 29/08; H01L 29/10

(52) U.S. Cl. CPC H01L 29/7397; H01L 29/1095; H01L 29/1004; H01L 29/0804; H01L 29/0821

(57) ABSTRACT

According to one embodiment, a semiconductor device includes a first semiconductor region, a second semiconductor region, a third semiconductor region, a fourth semiconductor region, a first gate electrode, a first region, and a second region. The third semiconductor region is provided on the second semiconductor region. The fourth semiconductor region is provided on the third semiconductor region. The first region is provided in the second semiconductor region. The first region is positioned between the first semiconductor region and the third semiconductor region. The second region is provided in the second semiconductor region. The second region is positioned between the first region and the gate electrode. A carrier density of the first conductivity type in the second region is higher than a carrier density of the first conductivity type in the first region.

### CROSS-REFERENCE TO RELATED APPLICATIONS

This application is based upon and claims the benefit of priority from Japanese Patent Application No. 2014-173984, filed on Aug. 28, 2014; the entire contents of which are incorporated herein by reference.

### FIELD

Embodiments described herein relate generally to a semiconductor device.

### BACKGROUND

A semiconductor device such as, for example, an insulated gate bipolar transistor (hereinafter, referred to as IGBT) is used as a switching element.

In IGBT, the amount of negative charges induced to a gate electrode by carrier existing in a semiconductor region is favorably small. When the amount of the induced negative charges becomes equal to or greater than a prescribed amount, the negative charges becomes to be stored more than positive charges in response to increase of a gate voltage, that is, negative capacitance is generated. When the negative capacitance is generated on the gate electrode, oscillation of the gate voltage and decrease of breakdown voltage may occur.

### BRIEF DESCRIPTION OF THE DRAWINGS

FIG. 1 is a plan view of a portion of a semiconductor device of a first embodiment;

FIGS. 2A and 2B are perspective views of the portion of the semiconductor device of the first embodiment;

FIG. 3 is a perspective view of a portion of a semiconductor device of a second embodiment;

FIG. 4 is a perspective view of a portion of a semiconductor device of a third embodiment;

FIG. 5 is a perspective view of a portion of a semiconductor device of a fourth embodiment;

FIG. 6 is a perspective view of a portion of a semiconductor device of a fifth embodiment;

FIGS. 7A and 7B are perspective views of a portion of a semiconductor device of a sixth embodiment; and

FIG. 8 is a graph diagram showing a simulation result of the semiconductor device of the first embodiment.

### DETAILED DESCRIPTION

According to one embodiment, a semiconductor device includes a first semiconductor region, a second semiconductor region, a third semiconductor region, a fourth semiconductor region, a first gate electrode, a first region, and a second region. The first semiconductor region has a second conductivity type. The second semiconductor region has a first conductivity type. The second semiconductor region is provided on the first semiconductor region. The third semiconductor region has the second conductivity type. The third semiconductor region is provided on the second semiconductor region. The fourth semiconductor region has the first conductivity type. The fourth semiconductor region is provided on the third semiconductor region. The first gate electrode is provided in the second semiconductor region, the third semiconductor region, and the fourth semiconductor region via a first insulating film. The first region is provided in the second semiconductor region. The first region is positioned between the first semiconductor region and the third semiconductor region. The second region is provided in the second semiconductor region. The second region is positioned between the first region and the gate electrode. A carrier density of the first conductivity type in the second region is higher than a carrier density of the first conductivity type in the first region.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

### First Embodiment

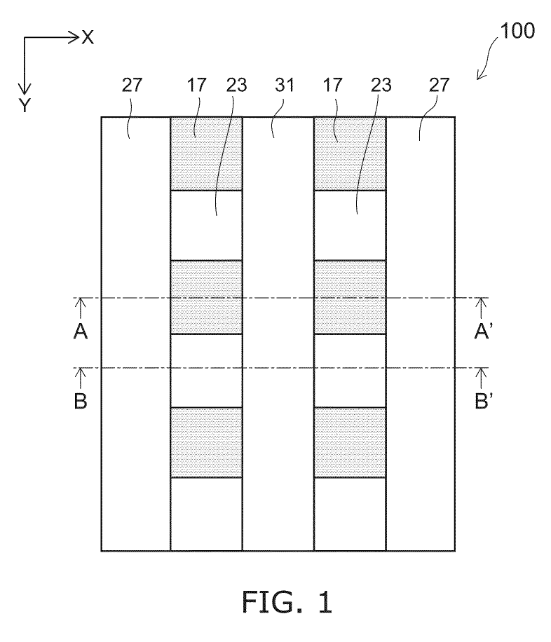

FIG. 1 is a plan view of a portion of a semiconductor device of a first embodiment.

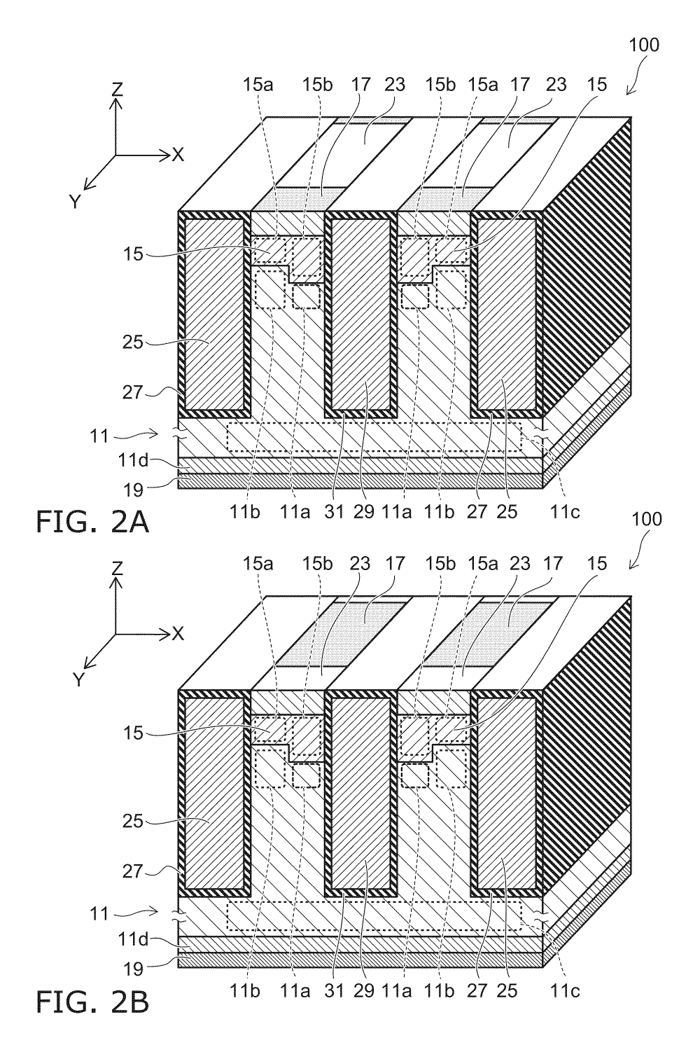

FIG. 2A and FIG. 2B are perspective views of the portion of the semiconductor device of the first embodiment.

FIG. 2A is a perspective view including A-A′ cross-section in FIG. 1, and FIG. 2B is a perspective view including B-B′ cross-section in FIG. 1.

In the embodiment, the case where a first conductivity type is n-type and a second conductivity type is p-type will be described. However, the first conductivity type may be p-type and the second conductivity type may be n-type.

A semiconductor device 100 is illustratively IGBT. The semiconductor device 100 includes a first semiconductor region of a second conductivity type, a second semiconductor region of a first conductivity type, a third semiconductor region of the second conductivity type, a fourth semiconductor region of the first conductivity type, a fifth semiconductor region of the second conductivity type, and a first gate electrode.

The first semiconductor region is, for example, a collector region 19. The second semiconductor region is, for example, an n-base region 11. The third semiconductor region is, for example, a p-base region 15. The fourth region is, for example, an emitter region 17. The fifth semiconductor region is, for example, a contact region 23.

In the description of following each embodiment, a direction from the collector region 19 toward the n-base region 11 is taken as a first direction. A direction orthogonal to the first direction is taken as a second direction. A direction orthogonal to the first direction and the second direction is taken as a third direction.

The first direction is, for example, a Z-direction shown in FIG. 1. The second direction is, for example, an X-direction shown in FIG. 1. The third direction is, for example, a Y-direction shown in FIG. 1.

The collector region 19 contacts a collector electrode not shown.

The n-base region 11 is provided on the collector region 19.

The n-base region 11 includes a first region 11a, a second region 11b, and a third region 11c.

The first region 11a and the second region 11b are provided between collector region 19 and p-base region 15. The second region 11b is provided between the first region 11a and gate electrode 25. A part of the third region 11c is provided between collector region 19 and p-base region 15. Another part of the third region 11c is provided between collector region 19 and gate electrode 25. Another part of the third region 11c is provided between collector region 19 and electrode 29. In other word, the third region 11c is provided between collector region 19 and p-base region 15, between collector region 19 and gate electrode 25, and between collector region 19 and electrode 29.

An impurity concentration of the first conductivity type in the first region 11a is higher than an impurity concentration of the first conductivity type in the third region 11c. The first region 11a is adjacent to the p-base region 15 in the Z-direction.

An impurity concentration of the first conductivity type in the second region 11b is higher than the impurity concentration of the first conductivity type in the first region 11a. The second region 11b is adjacent to the first region 11a in the X-direction. The second region 11b is adjacent to the p-base region 15 in the Z-direction.

The first region 11a and the second region 11b are located on the p-base region 15 side of the n-base region 11. That is, a distance between the first region 11a and the p-base region 15 is smaller than a distance between the third region 11c and the p-base region 15. A distance between the second region 11b and the p-base region 15 is smaller than the distance between the third region 11c and the p-base region 15.

The third region 11c is located on the collector region 19 side of the n-base region 11.

The first region 11a and the second region 11b extend in the Y-direction. The first region 11a and the second region 11b are provided on both regions of a region immediately below the emitter region 17 and a region immediately below the collector region 23 out of the n-base region 11.

The n-base region may include a fourth region 11d in the vicinity of an interface with the collector region 19. An impurity concentration of the first conductivity type in the fourth region 11d is lower than the impurity concentration of the first conductivity type in the third region 11c. The fourth region 11d is able to function as a buffer region.

The p-base region 15 is provided on the n-base region 11. In the example shown in FIG. 1, the p-base region 15 is selectively provided on the n-base region 11. The p-base region 15 extends in the Y-direction. The p-base region 15 is provided in a plurality in the X-direction.

The p-base region 15 includes a third region 15a and a fourth region 15b. The third region 15a is provided between the fourth region 15b and gate electrode 25.

The third region 15a is adjacent to the second region 11b in the Z-direction. The third region 15a is adjacent to the fourth region 15b in the X-direction.

The fourth region 15b is adjacent to the first region 11a in the Z-direction. An impurity concentration of the first conductivity type in the fourth region 15b is, for example, the same as an impurity concentration of the first conductivity type in the third region 15a. The fourth region 15b extends more to the collector region 19 side than the third region 15a. That is, a distance between the collector region 19 and an interface between the second region 11b and the third region 15a is larger than a distance between the collector region 19 and an interface between the first region 11a and the fourth region 15b. In other words, the interface between the n-base region 11 and the p-base region 15 includes a first interface and a second interface. The first interface is between the first region 11a and the fourth region 15b and the second interface is between the second region 11b and the third region 15a. A distance between a first interface and the collector region 19 is larger than a distance between a second interface and the collector region 19.

At least a portion of the fourth region 15b is provided immediately above the first region 11a. In other words, at least a portion of the fourth region 15b is arranged with the first region 11a in the Z-direction. In other expression, a position of at least a portion of the fourth region 15b in the X-direction is the same as a position of the first region 11a in the X-direction.

A portion of the second region 11b is provided at the same depth as a portion of the fourth region 15b. In other words, a position of a portion of the second region 11b in the Z-direction is the same as a position of a portion of the fourth region 15b in the Z-direction. That is, the portion of the second region 11b and the portion of the fourth region 15b are provided at the same position in the Y-direction from the n-base region 11 towards the p-base region 15, the Y-direction being orthogonal to the X-direction. In other expression, the portion of the second region 11b is arranged with the portion of the fourth region 15b in the X-direction.

The emitter region 17 is selectively provided on the p-base region 15. As shown in FIG. 1, the emitter regions are separated each other and provided in a plurality in the X-direction and the Y-direction. That is, the emitter regions 17 are separated each other and provided in a plurality in the Y-direction on the p-base region 15 extending in the Y-direction.

An emitter electrode not shown is provided on the emitter region 17. The emitter region 17 contacts the emitter electrode.

The contact region 23 is selectively provided on the p-base region 15. The collector regions 23 are separated each other and provided in a plurality in the X-direction and the Y-direction. The contact region 23 is provided to be located between the emitter regions 17 in the Y-direction. The contact regions 23 are separated each other and provided in a plurality on the p-base region 15 extending in the Y-direction similar to the emitter regions 17.

Although the contact regions 23 are not necessary in the embodiment, it is favorably provided in order to exhaust carrier (hole) of the second conductivity type efficiently.

A gate electrode 25 is opposed to the n-base region 11, the p-base region 15, and the emitter region 17 via a first insulating film 27.

An electrode 29 is opposed to the n-base region 11, the p-base region 15, and the emitter region 17 via a second insulating film 31.

The gate electrode 25 and the electrode 29 are alternately provided in the X-direction. A portion of the n-base region 11, the p-base region 15, and at least a portion of the emitter region 17 are provided between the adjacent gate electrode 25 and the electrode 29.

The gate electrode 25 and the electrode 29 are formed, for example, by burying an electrode material into a trench. For example, polysilicon is possible to be used for a material of the gate electrode 25 and a material of the electrode 29. For example, oxide silicon is possible to be used for a material of the first insulating film 27 and a material of the second insulating film 31.

The gate electrode 25 is adjacent to the second region 11b via the first insulating film 27. That is, a distance between the first region 11a and the gate electrode 25 in the X-direction is larger than a distance between the second region 11b and the gate electrode 25 in the X-direction. For this reason, in a region between the gate electrode 29 and the electrode 25, an impurity concentration of the first conductivity type in the n-base region (second region 11b) in the vicinity of the gate electrode 25 is higher than an impurity concentration of the first conductivity type in the n-base region (first region 11a) in the vicinity of the electrode 29.

The electrode 29 is adjacent to the first region 11a via the second insulating film 31. That is, a distance between the second region 11b and the electrode 29 in the X-direction is larger than a distance between the first region 11a and the electrode 29 in the X-direction.

A channel (inversion layer) to a carrier (electron) of the first conductivity type is formed in a region of the p-base region 15 in the vicinity of the first insulating film 27 by applying a voltage to the gate electrode 25. The electrode 29 is connected to, for example, the emitter electrode and connected to a ground potential. When the electrode 29 is connected to the ground potential, it is able to function as a field plate electrode.

The impurity concentrations in the respective semiconductor regions are illustrated in the following. Values of the respective impurity concentrations represent the impurity concentration of each conductivity type after the impurity of the first conductivity type and the impurity of the second conductivity type are compensated each other.

The impurity concentration in the second region 11b of the n-base region 11 is 1.0×10¹⁶ to 1.0×10¹⁸ atom/cm³.

The impurity concentration in the third region 11c of the n-base region 11 is 1.0×10¹³ to 1.0×10¹⁴ atom/cm³.

The impurity concentration in the first region 11a is lower than the impurity concentration in the second region 11b, and higher than the impurity concentration in the third region 11c.

The impurity concentration in the p-base region 15 is 1.0×10¹⁶ to 1.0×10¹⁸ atom/cm3.

The impurity concentration in the p-base region 15 is higher than that of the third region 11c.

The impurity concentration in the emitter region 17 is 1.0×10¹⁸ to 1.0×10²⁰ atom/cm³.

The impurity concentration in the contact region 23 is 1.0×10¹⁸ to 1.0×10²⁰ atom/cm³.

The impurity concentrations in the emitter region 17 and the contact region 23 are higher than any of the impurity concentrations of the third region 11c, the second region 11b, and the p-base region 15.

The first region 11a and the second region 11b may be formed by n-type impurities ion implantation to a part of n-base region 11 after the n-base region 11 is formed. The p-base region 15 may be formed by p-type impurities ion implantation to a part of a surface of n-base region 11 after the n-base region 11, the first region 11a, and the second region 11b are formed.

The emitter region 17 may be formed by n-type impurities ion implantation to a part of a surface of the p-base region 15 after the p-base region 15 is formed. The contact region 23 may be formed by p-type impurities ion implantation to another part of the surface of the p-base region 15 after the emitter region 17 is formed.

The gate electrode 25 may be formed after the n-base region 11, p-base region 15, emitter region 17, and contact region 23 are formed. In this case, a trench penetrating the n-base region 11, p-base region 15, and the emitter region 17 is formed, and then the gate electrode 25 is formed by forming an insulating film and a metal film inside the trench.

The gate electrode 25 may be formed before p-base region 15, emitter region 17, and contact region 23 is formed. In this case, p-base region 15, emitter region 17, and contact region 23 is formed after trenching a part of n-base region 11 and forming the gate electrode 25 inside the trench.

When the semiconductor device 100 is on-operated, holes flow in a region between the gate electrode 25 and the electrode 29 in a direction from the collector electrode toward the emitter electrode.

If the first region 11a and the second region 11b are provided, many holes pass through the first region 11a having a low impurity concentration of the first conductivity type when flowing the region between the gate electrode 25 and the electrode 29. For this reason, the density of hole in the vicinity of the gate electrode 25 can be lowered and negative charges induced to the electrode 25 can be reduced.

If the second region 11b having high impurity concentration of the first conductivity type is provided, the carrier storage amount in the n-base region 11 is increased in comparison with the case where the second region 11b is not provided. For this reason, it becomes possible to enhance IE (Injection Enhanced) effect and to reduce an on-voltage of the semiconductor device 100.

Furthermore, more holes pass through the position (fourth region 15b) distant from the gate electrode 25 by forming the third region 15a and the fourth region 15b so as to the third region 15a being between the fourth region 15b and the gate electrode 25.

At this time, more holes pass through the position distant from the gate electrode 25 by providing the fourth region 15b immediately above the first region 11a where holes pass through easier than the second region 11b.

If the portion of the second region 11b and the portion of the fourth region 15b are provided at the same position in the second direction, the number of holes passing through the vicinity of the gate electrode 25 can be reduced in comparison with the case where the portion of the second region 11b and the portion of the fourth region 15b are not provided at the same depth.

The interface between the semiconductor region of the first conductivity type and the semiconductor region of the second conductivity type can be more approximated to the second region 11b by adopting the configuration described above. Because the holes which pass through the first region 11a can be suppressed from diffusing into the region between the second region 11b and the third region 15a as a result of adoption of the above configuration.

Here, the case where the second region 11b exists uniformly in the semiconductor region between the gate electrode 25 and the electrode 29 is conceived. The second region 11b functions as a potential barrier to the holes, the potential barrier uniformly existing between the gate electrode 25 and the electrode 29. As a result, the holes are drawn to electrons flowing in a channel formed in the vicinity of the first insulating film 27, and flow the vicinity of the first insulating film 27 to pass through the n-base region 11. Therefore, the density of hole in the vicinity of the first insulating film 27 increases and a large amount of negative charges are induced to the gate electrode 25.

In contrast, in the embodiment, by providing the first region and the second region 11b having the impurity concentration of the first conductivity type higher than the first region, the holes can be suppressed from passing through the vicinity of the first insulating film 27 and the negative charges induced to the gate electrode 25 are reduced.

### Second Embodiment

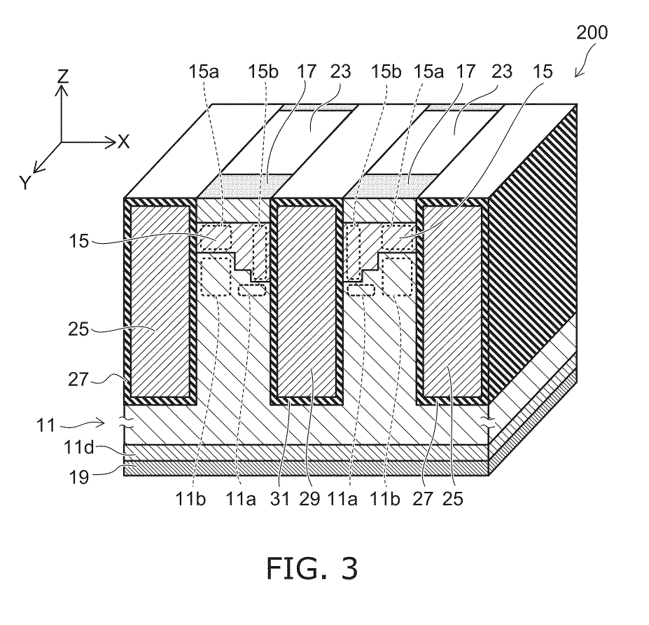

FIG. 3 is a perspective cross-sectional view of a portion of a semiconductor device 200 according to a second embodiment.

A difference between the embodiment and the first embodiment is in the fourth region 15b of the p-base region 15.

In a semiconductor device 200, the p-base region 15 includes the third region 15a and the fourth region 15b similarly to the semiconductor device 100. However, an impurity concentration of the second conductivity type in the fourth region 15b is higher than an impurity concentration of the second conductivity type in the third region 15a. The fourth region 15b extends more to the collector region 19 side than the third region 15a. The impurity concentration of the second conductivity type in the fourth region 15b is, for example, 1.0×10¹⁶ to 1.0×10¹⁸ atom/cm³.

The distance between the fourth region 15b and the gate electrode 25 is larger than the distance between the third region 15a and the gate electrode 25. That is, inside the p-base-region 15, the third region 15a is located in the vicinity of the gate electrode 25 and the fourth region 15b is located in the vicinity of the electrode 29.

The potential barrier of the fourth region 15b is lower than the potential barrier of the third region 15a to holes. For this reason, since the distance between the fourth region 15b and the gate electrode 25 is larger than the distance between the third region 15a and the gate electrode 25, more holes pass through the position (fourth region 15b) distant from the gate electrode 25.

According to the embodiment, more holes pass through the region distant from the gate electrode 25 in comparison with the first embodiment. As a result, the density of hole in the vicinity of the first insulating film 27 further decreases and the negative charges induced to the gate electrode 25 are reduced.

### Third Embodiment

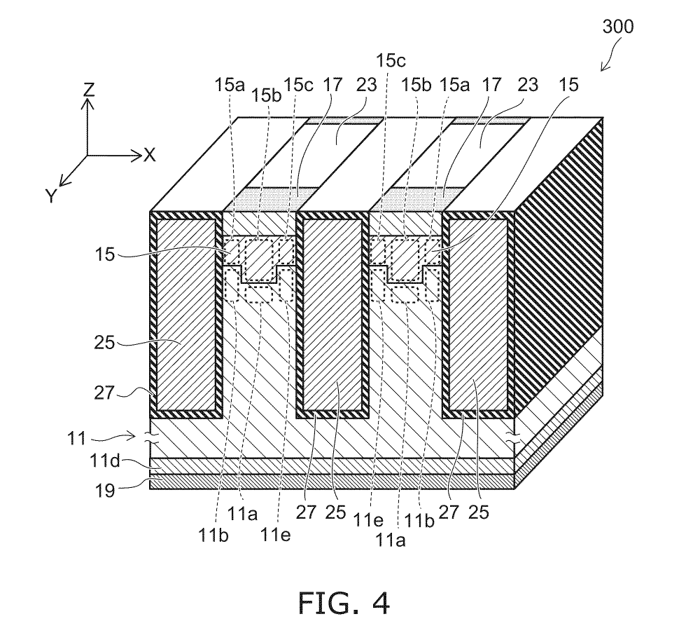

FIG. 4 is a perspective cross-sectional view of a portion of a semiconductor device 300 according to a third embodiment.

In the embodiment, the electrode 29 is not provided between the gate electrodes 25. That is, the gate electrodes 25 are adjacently provided one another in the Y-direction.

The n-base region 11 includes the first region 11a, the second region 11b, and a fifth region 11e in a region between adjacent gate electrodes 25.

The first region 11a is provided in a region between the second region 11b and the fifth region 11e.

The impurity concentration of the first conductivity type in the second region 11b is higher than the impurity concentration of the first conductivity type in the first region 11a.

An impurity concentration of the first conductivity type in the fifth region 11e is higher than the impurity concentration of the first conductivity type in the first region 11a. The fifth region is adjacent to the first insulating film 27.

The distance between the second region 11b and the gate electrode 25 (first gate electrode) adjacent to the second region 11b is smaller than the distance between the first region 11a and the gate electrode 25 adjacent to the second region 11b. That is, the first region 11a is more distant from the first insulating film 27 than the second region 11b.

A distance between the fifth region 11e and the gate electrode (second gate electrode) adjacent to the fifth region 11e is smaller than a distance between the first region 11a and the gate electrode 25 adjacent to the fifth region 11e. That is, the first region 11a is more distant from the first insulating film 27 than the fifth region 11e.

The p-base region 15 includes the third region 15a, the fourth region 15b, and a sixth region 15c.

The fourth region 15b is provided between the third region 15a and the sixth region 15c.

The impurity concentration of the second conductivity type in the fourth region 15b is, for example, equal to the impurity concentration of the second conductivity type in the third region 15a. The impurity concentration of the second conductivity type in the fourth region 15b is, for example, equal to an impurity concentration of the second conductivity type in the sixth region 15c.

The fourth region 15b extends more to the collector region 19 side than the third region 15a and the sixth region 15c. In other words, a distance between the first interface and the collector region 19 is smaller than a distance between a third interface and the collector region 19. The first interface is, as described in the first embodiment, between the first region 11a and the fourth region 15b. The third interface is a part of the interface between the n-base region 11 and the p-base region 15 and is between the fifth region 11e and the sixth region 15c.

The sixth region 15c is adjacent to the fifth region 11e in the Z-direction.

The distance between the gate electrode 25 (first gate electrode) adjacent to the third region 15a and the fourth region 15b is larger than the distance between the gate electrode 25 adjacent to the third region 15a and the third region 15a. That is, the fourth region 15b is more distant from the first insulating film 27 than the third region 15a.

A distance between the gate electrode 25 (second gate electrode) adjacent to the sixth region 15c and the fourth region 15b is larger than a distance between the gate electrode 25 adjacent to the sixth region 15c and the sixth region 15c. That is, the fourth region 15b is more distant from the first insulating film 27 than the sixth region 15c.

At least a portion of the third region 15a is located immediately above the second region 11b. In other words, at least the portion of the third region 15a is arranged with the second region 11b in the Z-direction. In other expression, a position of at least the portion of the third region 15a in the X-direction is the same as a position of the second region 11b in the X-direction.

At least a portion of the fourth region 15b is located immediately above the first region 11a. In other words, at least the portion of the fourth region 15b is arranged with the first region 11a in the Z-direction. In other expression, a position of at least the portion of the fourth region 15b in the X-direction is the same as a position of the first region 11a in the X-direction.

At least a portion of the sixth region 15c is located immediately above the fifth region 11e. In other words, at least the portion of the sixth region 15c is arranged with the fifth region 11e in the Z-direction. In other expression, a position of at least the portion of the sixth region 15c in the X-direction is the same as a position of the fifth region 11e in the X-direction.

In this case, when holes flow between mutually adjacent gate electrodes 25, many holes pass through the first region 11a and the fourth region 15b distant from the gate electrode 25.

Also in the embodiment, the density of hole in the vicinity of the first insulating film 27 decreases, and thus the negative charges induced to the gate electrode 25 are reduced.

### Fourth Embodiment

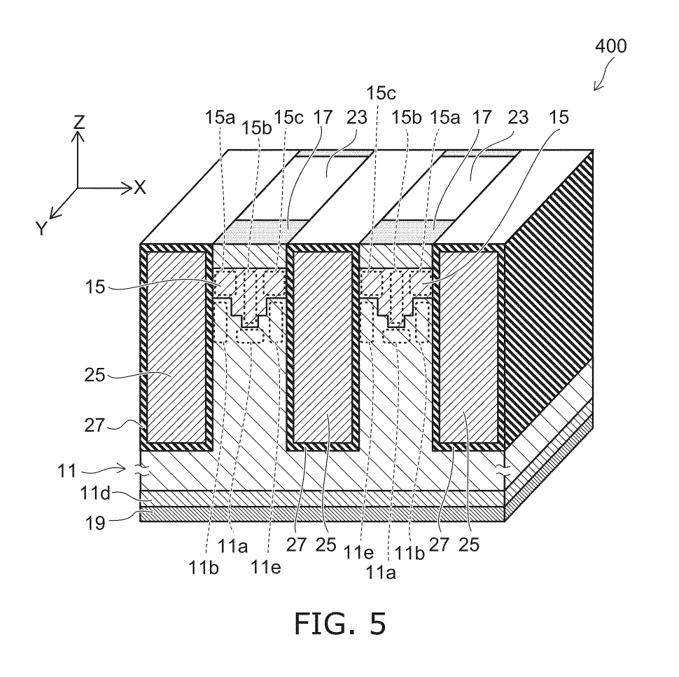

FIG. 5 is a perspective cross-sectional view of a portion of a semiconductor device 400 according to a fourth embodiment.

A difference between the embodiment and the third embodiment is in the fourth region 15b of the p-base region 15.

In the semiconductor device 300, the p-base region 15 includes the third region 15a, the fourth region 15b, and the sixth region 15c similarly to the semiconductor device 200.

However, the impurity concentration of the second conductivity type in the fourth region 15b is higher than the impurity concentration of the second conductivity type in the third region 15a. The impurity concentration of the second conductivity type in the fourth region 15b is higher than the impurity concentration of the second conductivity type in the sixth region 15c. The impurity concentration of the second conductivity type in the fourth region 15b is, for example, 1.0×10¹⁶ to 1.0×10¹⁸ atom/cm³.

Other relationships between the fourth region 15b and the third region 15a and between the fourth region 15b and the sixth region 15c are the same as the relationships in the third embodiment.

Relationships between the gate electrode 25 and the third region 15a, between the gate electrode 25 and the fourth region 15b, and between the gate electrode 25 and the sixth region 15c are also the same as the relationships in the third embodiment.

The potential barrier of the fourth region 15b is lower than the potential barrier of the third region 15a to holes.

Since the distance between the fourth region 15b and the gate electrode 25 is larger than the distance between the third region 15a and the gate electrode 25 adjacent to the third region 15a, more holes pass through the position distant from the gate electrode 25 adjacent to the third region 15a.

Since the distance between the fourth region 15b and the gate electrode 25 is larger than the distance between the sixth region 15c and the gate electrode 25 adjacent to the sixth region 15c, more holes pass through the position distant from the gate electrode 25 adjacent to the sixth region 15c.

That is, more holes pass through the position distant from both gate electrodes 25 of the gate electrode 25 adjacent to the third region 15a and the gate electrode 25 adjacent to the sixth region 15c.

According to the embodiment, more holes pass through the first region 11a and the fourth region 15b distant from the gate electrode 25 in comparison with the third embodiment. As a result, the density of hole in the vicinity of the first insulating film 27 further decreases, and thus the negative charges induced to the gate electrode 25 are reduced.

### Fifth Embodiment

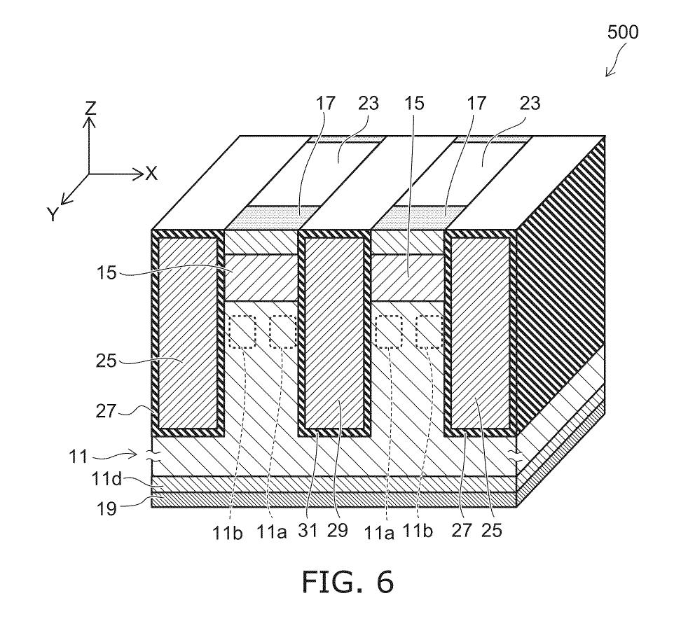

FIG. 6 is a perspective cross-sectional view of a portion of a semiconductor device 500 according a fifth embodiment.

In the embodiment, the n-base region 11 includes the first region 11a and the second region 11b. The second region 11b has a higher impurity concentration of the first conductivity type than the first region 11a. The second region 11b is provided at a position distant from an interface between the n-base region 11 and the p-base region 15 in the n-base region 11 in comparison with the first embodiment.

In the first embodiment, a position of the interface between the n-base region 11 and the p-base region 15 immediately above the first region 11a in the Z-direction is different from a position of the interface between the n-base region 11 and the p-base region 15 immediately above the second region 11b in the Z-direction.

In contrast, in the embodiment, a position of the interface between the n-base region 11 and the p-base region 15 immediately above the first region 11a in the Z-direction is substantially the same as a position of the interface between the n-base region 11 and the p-base region 15 immediately above the second region 11b in the Z-direction.

The second region 11b is formed by injecting an impurity into a position deeper than a position where a lower end of the p-base region 15 is formed. For this reason, effects of diffusion of the impurity of the first conductivity type to the p-base region 15 in forming the second region 11b is smaller than effects of diffusion of the impurity of the first conductivity type to the p-base region 15 in forming the second region 11b in the first embodiment.

When forming the first region 11a, the impurity is injected into the deeper position than the lower end of the p-base region 15, and thereby when forming the first region 11a by the following heat treatment, the amount of the impurity of the first conductivity type diffusing into the p-base region 15 is reduced. For this reason, the amount of the impurity of the first conductivity type to be compensated becomes small in the p-base region 15 serving as a channel formation region as well. As a result, according to the embodiment, similar to other embodiments, it becomes possible to suppress variation of the impurity concentration in the p-base region 15 in every processed substrate, while decreasing the density of hole in the vicinity of the first insulating film 27.

### Sixth Embodiment

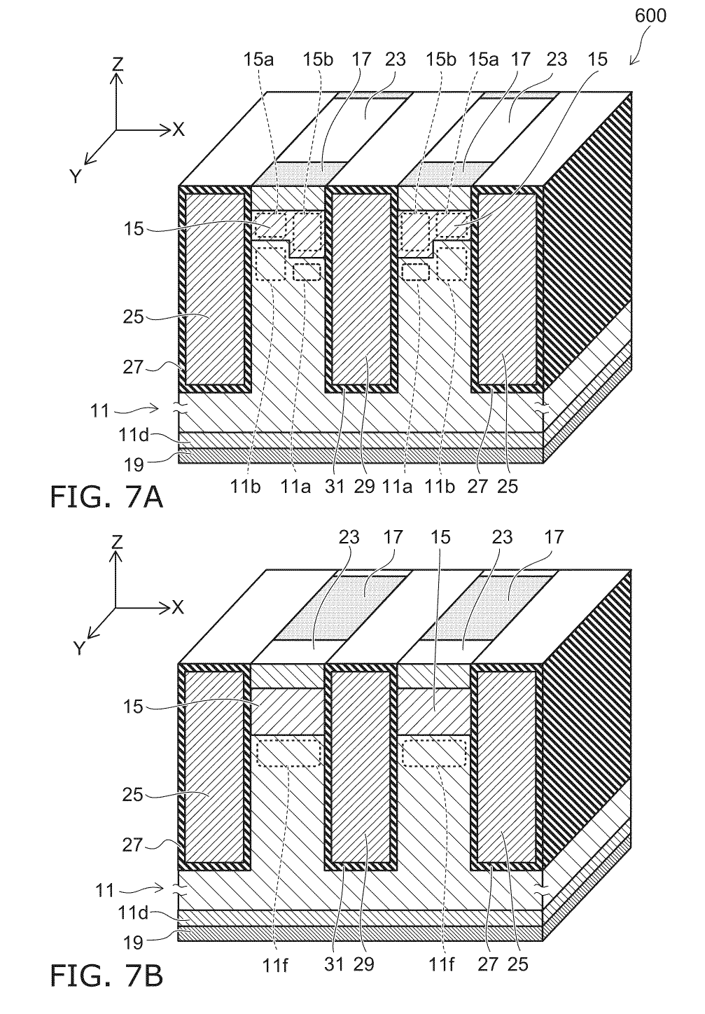

FIG. 7A and FIG. 7B are perspective cross-sectional views of a portion of a semiconductor device 600 according to a sixth embodiment.

FIGS. 7A and 7B show cross sections of positions different each other.

The embodiment is different from the first embodiment in a point that the second region 11b is not provided in at least a portion of a region immediately below the contact region 23. That is, the second region 11b is not provided in at least a portion of the region arranged with the contact region 23 in the Z-direction out of the n-base region 11. In other expression, at the position of the second region 11b, a region with a high impurity concentration of the first conductivity type and a region with a low impurity concentration of the first conductivity type are alternately provided in the Y-direction.

In the embodiment, the impurity concentration of the first conductivity type in a region immediately below the contact region 23 out of the n-base region 11, the holes being exhausted from the contact region 23, is lower than the impurity concentration of the first conductivity type in a region immediately below the emitter region 17 out of the n-base region 11. For this reason, the holes are exhausted more efficiently from the n-base region 11 than the first embodiment. Therefore, the density of hole stored in the vicinity of the first insulating layer 27 is further reduced in comparison with the first embodiment, and the negative charges induced to the gate electrode 25 are further reduced.

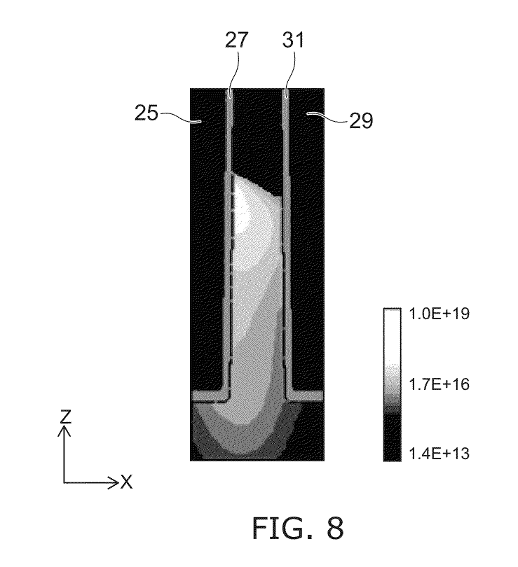

FIG. 8 is a result of simulation of the semiconductor device according to the first embodiment.

FIG. 8 shows a distribution of the impurity concentration of the first conductivity type in the region between the gate electrode 25 and the electrode 29. The impurity distribution in each region shows the impurity concentration of the first conductivity type after the impurity of the first conductivity type and the impurity of the second conductivity type are compensated each other.

In the gray scale distribution in FIG. 8, it is shown that the impurity concentration of the first conductivity type is higher with being more white (pale), and the impurity concentration of the first conductivity type is lower with being black (deep).

In FIG. 8, the whole impurity region of the second conductivity type is indicated by black color regardless of the concentration.

A unit of the numerical values shown in the scale of FIG. 8 is atom/cm³.

It is found from this simulation results that a gradient of the impurity concentration of the first conductivity type is formed in the direction (X-direction) from the gate electrode 25 toward the electrode 29 in the region between the gate electrode 25 and the electrode 29. It is found that a distance between a region with the high impurity concentration of the first conductivity type and the gate electrode 25 is smaller than a distance between a region with the lower impurity concentration of the first conductivity type than this region and the gate electrode 25.

It is found that a depth of the p-base region becomes deep with approaching from the gate electrode 25 toward the electrode 29 in the region between the gate electrode 25 and the electrode 29. That is, it is found that the p-base region 15 includes the region extending to the collector region 19 side, and the region exists at a position distant from the gate electrode 25.

A carrier density of each semiconductor region is proportionate to an impurity concentration of each of the semiconductor region. So a relative extent of an impurity concentration in each semiconductor region can be understood as a relative extent of a carrier density in the each semiconductor region.

The relative concentration of the impurity in each semiconductor region described above and described in respective embodiments can be confirmed, for example, by using SCM (scanning electrostatic capacity microscope).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A semiconductor device comprising:
a first semiconductor region of a second conductivity type;
a second semiconductor region of a first conductivity type provided on the first semiconductor region;
a third semiconductor region of the second conductivity type provided on the second semiconductor region;
a fourth semiconductor region of the first conductivity type provided on the third semiconductor region;
a first gate electrode provided in the second semiconductor region, the third semiconductor region, and the fourth semiconductor region via a first insulating film;
a first region provided in the second semiconductor region and positioned between the first semiconductor region and the third semiconductor region; and
a second region provided in the second semiconductor region and positioned between the first region and the gate electrode, a carrier density of the first conductivity type in the second region is higher than a carrier density of the first conductivity type in the first region, the second region contacting the first insulating film.

2. The device according to claim 1, further comprising:
a fourth region provided in the third semiconductor region and positioned between the first region and the fourth semiconductor region; and
a third region provided in the third semiconductor region and positioned between the fourth region and the first gate electrode,
a distance between a first interface and the first semiconductor region being smaller than a distance between the second interface and the first semiconductor region,
the first interface being a part of an interface between the second semiconductor region and the third semiconductor region and being positioned between the first region and the fourth region, and
the second interface being a part of the interface between the second semiconductor region and the third semiconductor region and being positioned between the second region and the third region.

3. The device according to claim 2, wherein
a carrier density of the second conductivity type in the fourth region is higher than a carrier density of the second conductivity type in the third region.

4. The device according to claim 1, further comprising:
an electrode provided in the second semiconductor region, the third semiconductor region, and the fourth semiconductor region via a second insulating film;
the first region being adjacent to the second insulating film; and
the second region being more distant from the second insulating film than the second region.

5. The device according to claim 1, further comprising:
a second gate electrode provided in the second semiconductor region, the third semiconductor region, and the fourth semiconductor region via the second insulating film; and
a fifth region provided in the second semiconductor region and positioned between the first region and the second gate electrode, a carrier density of the first conductivity type in the fifth region being higher than a carrier density of the first conductivity type in the first region.

6. The device according to claim 5, further comprising:
a fourth region provided in the third semiconductor region and positioned between the first region and the fourth semiconductor region; and
a third region provided in the third semiconductor region and positioned between the fourth region and the first gate electrode,
a distance between a first interface and the first semiconductor region being smaller than a distance between the second interface and the first semiconductor region,
the first interface being a part of an interface between the second semiconductor region and the third semiconductor region and being positioned between the first region and the fourth region, and
the second interface being a part of the interface between the second semiconductor region and the third semiconductor region and being positioned between the second region and the third region.

7. The device according to claim 6, further comprising:
a fifth region provided in the second semiconductor region and positioned between the first region and the second gate electrode;
a sixth region provided in the third semiconductor region and positioned between the fourth region and the second gate electrode;
a distance between a third interface and the first semiconductor region is larger than a distance between the first interface and the first semiconductor region; and
the third interface being a part of the interface between the second semiconductor region and the third semiconductor region and being positioned between the fifth region and the sixth region.

8. The device according to claim 7, wherein
a carrier density of the second conductivity type in the fourth region is higher than a carrier density of the second conductivity type in the third region and a carrier density of the second conductivity type in the sixth region.

9. The device according to claim 2, wherein
a position of a portion of the second region in a first direction is equal to a position of a portion of the fourth region in the first direction, and
the first direction is from the first semiconductor region toward the second semiconductor region.

10. The device according to claim 1, further comprising:
a fifth semiconductor region of the second conductivity type selectively provided on the third semiconductor region.

11. The device according to claim 10, wherein
a carrier density of the second conductivity type in the fifth semiconductor region is higher than a carrier density of the second conductivity type in the third semiconductor region.

12. The device according to claim 11, wherein
the second region is not provided in at least a portion of a region of the second semiconductor region,
the region of the second semiconductor region is arranged with the fifth semiconductor region in a first direction from the first semiconductor region toward the second semiconductor region.

13. The device according to claim 1, wherein
a carrier density of the first conductivity type in the fourth semiconductor region is higher than a carrier density of the second conductivity type in the third semiconductor region.

14. The device according to claim 1, further comprising:
a seventh region provided on a side of the first semiconductor region in the second semiconductor region,
a carrier density of the first conductivity type in the seventh region being lower than a carrier density of the first conductivity type in the first region and a carrier density of the second conductivity type in the second region.
